(19) United States
(12) Patent Application Publication
(10) Pub. No.: US 2007/0056621 A1
(43) Pub. Date: Mar. 15, 2007

(54) Self-assembled thin film thermoelectric device

(76) Inventor: Rajashree Baskaran, Phoenix, AZ (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/227,576

(22) Filed: Sep. 14, 2005

(51) Int. Cl. H01L 35/34; H01L 35/28

(52) U.S. Cl. 136/201; 136/203

(57) ABSTRACT

A self-assembled thin film thermoelectric device useful for thermal management of semiconductor devices, for medical treatment, or for other applications where precise, efficient, and controlled heating or cooling may be useful. TEC elements, including n-type TEC elements and p-type TEC elements may be self-assembled to binding sites on a substrate, and alternating TEC element types may be electrically coupled to each other with metallization in a serial circuit arrangement. A substrate suitable for self-assembly of a TFTEC device may include heat generating devices, cooling devices, or thermally neutral devices. Binding sites may be provided or activated so that TEC elements may be attracted to, aligned with, or attached to the binding sites.

### FIELD OF THE INVENTION

The invention relates generally to the field of thermal management. In particular, the present invention relates to a thin film thermoelectric cooling (TFTEC) device.

### BACKGROUND OF THE INVENTION

Until recently, operating semiconductor devices have generated only such amounts of heat while operating to allow them to be sufficiently cooled based on passive thermal conduction and air cooling. However, several recent factors, including more densely integrated circuit designs, higher operating speeds and higher power demands, have led to successive generations of semiconductor devices requiring more active, effective cooling solutions. Included among the solutions proposed and implemented are liquid-vapor phase change solutions, refrigeration, thermoelectric coolers (TECs), and others.

Despite the numerous cooling solutions in use and proposed for use, few are able to efficiently and effectively address the presence of ‘hot spots’ in semiconductor devices, that is, areas of a semiconductor device with significantly higher thermal output than the rest of the device. Most current active cooling devices are designed to remove heat relatively uniformly across their effective surface area, with variations driven more by the physics of the materials involved and rates of thermal conduction across a thermal differential than by the design and structure of the cooling device. Most current and proposed cooling solutions must be large enough and effective enough, across their entire effective dimensions (e.g., length and width), to meet the needs of the hot spots while also cooling other portions of the semiconductor device. These objectives are further complicated as the size of semiconductor devices and packages shrink as a result of technology developments, and lead to larger, inefficient cooling devices that increase the overall size of the device in which they are used. Consequently, these cooling solutions either may not be used in smaller and/or more mobile devices, or they will drive an increase in the size of those devices, making them less desirable in a consumer market increasingly demanding small size, convenience, and portability.

One proposed solution is the use of thin film thermoelectric coolers (TFTEC) placed directly onto a semiconductor device. TECs contain dissimilar materials, which, when subjected to a current, generate a thermal differential whereby one type of junction within the device heats up and another type of junction cools down. Most TECs exist as modules that are large enough to be assembled onto semiconductor devices by a ‘pick and place’ manual or automated assembly process. Further, their larger size typically requires that they be placed atop an intermediate thermally conductive cooling device such as an integrated heat spreader (IHS). The IHS and the various thermal interface materials typically used both between an IHS and a semiconductor device, and between an IHS and a TEC, reduce the efficiency of the TEC for cooling the semiconductor device by increasing resistance to thermal flow. To be most effective, TECs should be placed as close as possible to the semiconductor device where the heat is generated, with as few intervening materials as possible. This means placing the TEC between the semiconductor device and an integrated heat spreader or another larger scale passive or active cooling device, or possibly even on the semiconductor die itself.

TFTECs take the concept of a TEC and shrink it from a module down to the scale of a thin ‘film’. The small size of TFTEC devices may allow them to be used in applications demanding a very small but effective cooling solution, however, their size also renders them difficult to assemble into or onto semiconductor devices in high volume manufacturing. The pick and place method by which nearly all assembly equipment operates will not work for TFTECs, and no other method is known today by which devices the size and complexity of TFTECs may be assembled to semiconductor devices in a high volume manufacturing environment.

In the field of microelectromechanical systems (MEMS), large numbers of very small devices may be manufactured, often through monolithic processing of silicon substrates. However, MEMS manufacturing techniques may not be readily applicable nor adaptable to produce small devices that may contain numerous disparate materials.

### BRIEF DESCRIPTION OF THE DRAWINGS

FIG. 1 depicts a module level TEC device according to the prior art

FIG. 2a-2i depicts a self-assembly method according to the prior art

FIG. 3 depicts a block diagram of a method for self-assembly of a TFTEC according to an embodiment of the invention

FIG. 4a-4f depicts a method for self-assembly of a TFTEC according to embodiments of the invention

FIG. 5a depicts a top view of a TFTEC apparatus according to embodiments of the invention

FIG. 5b depicts a cross-sectional view of a TFTEC apparatus according to embodiments of the invention

FIG. 6 depicts an embodiment of a self-assembled TFTEC provided upon a device with higher TEC element packing density adjacent to a hot spot on the device than adjacent to other areas of the device.

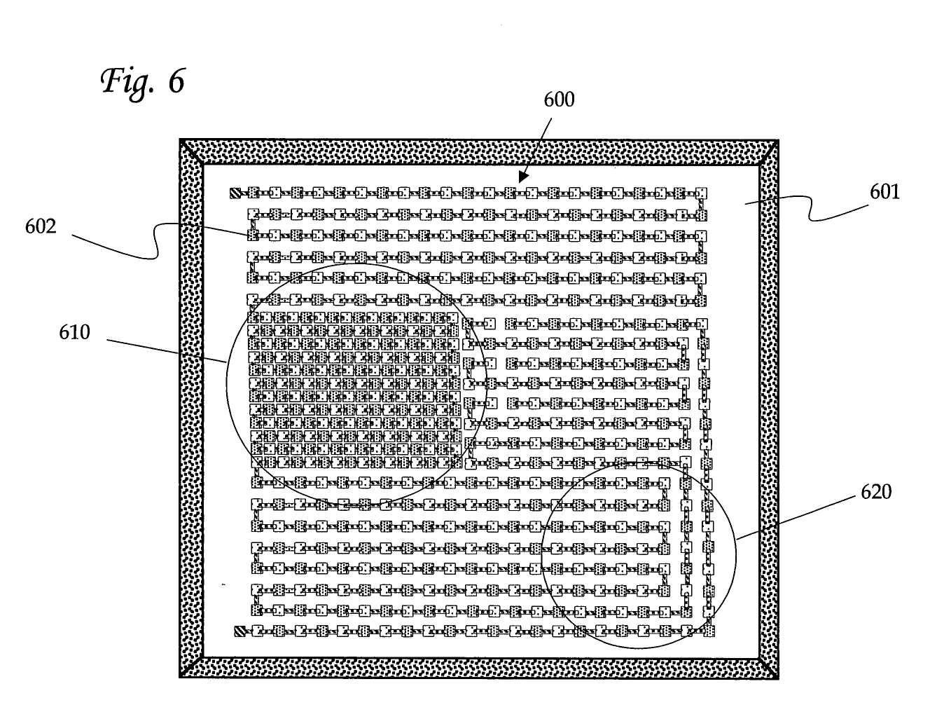

FIG. 7 depicts a cross-sectional view of a TFTEC assembly according to embodiments of the invention

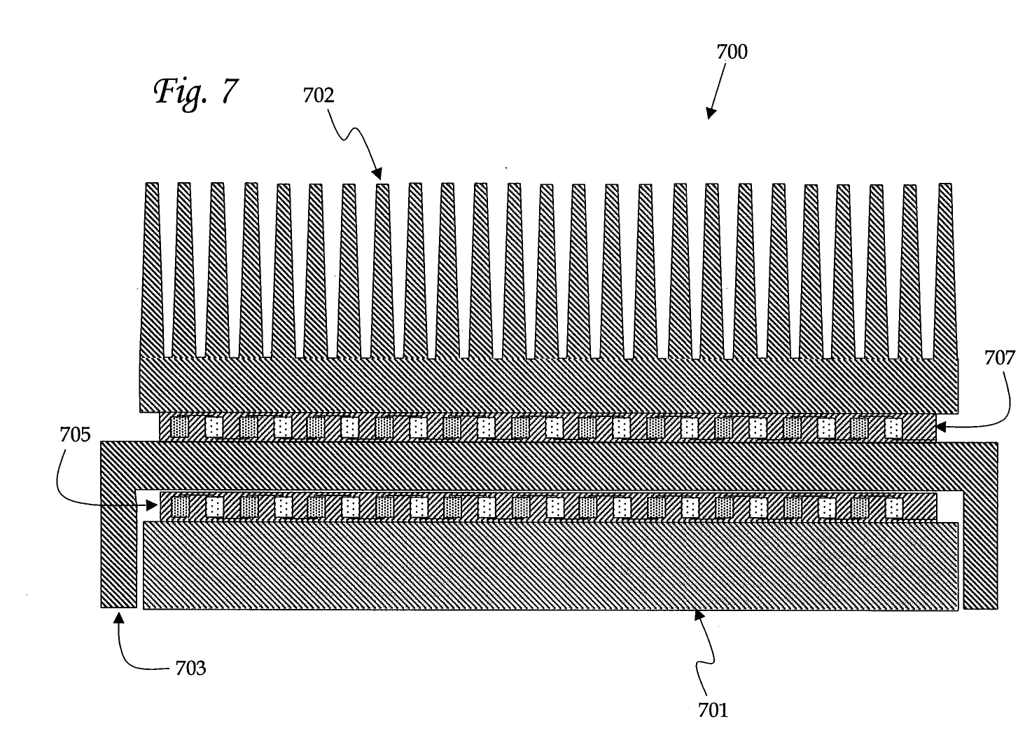

### DETAILED DESCRIPTION OF THE INVENTION

Described herein are embodiments of a method whereby thin film devices, such as thin film thermoelectric coolers (TFTEC) in an exemplary embodiment, may be self-assembled, as well as an apparatus and assembly so assembled. In embodiments, thin film devices may be self-assembled in substantial quantities, whereby the embodiments may be suitable for use in high volume manufacturing. In other embodiments, a large number of thin film devices may be self-assembled within a relatively small amount of surface area of a substrate, whereby their effectiveness may be increased at the same time that their size is reduced as compared to module level TEC devices.

In an exemplary embodiment, a large number of TFTEC elements may be placed adjacent to, or corresponding to, a hot spot on a semiconductor device, thereby concentrating a large amount of cooling capacity in close proximity to the hot spot. Embodiments of the invention also may allow self-assembly of other thin film devices that include multiple, disparate materials. Throughout this description, self-assembled TFTECs will be described as an exemplary embodiment of the invention, for convenience and clarity.

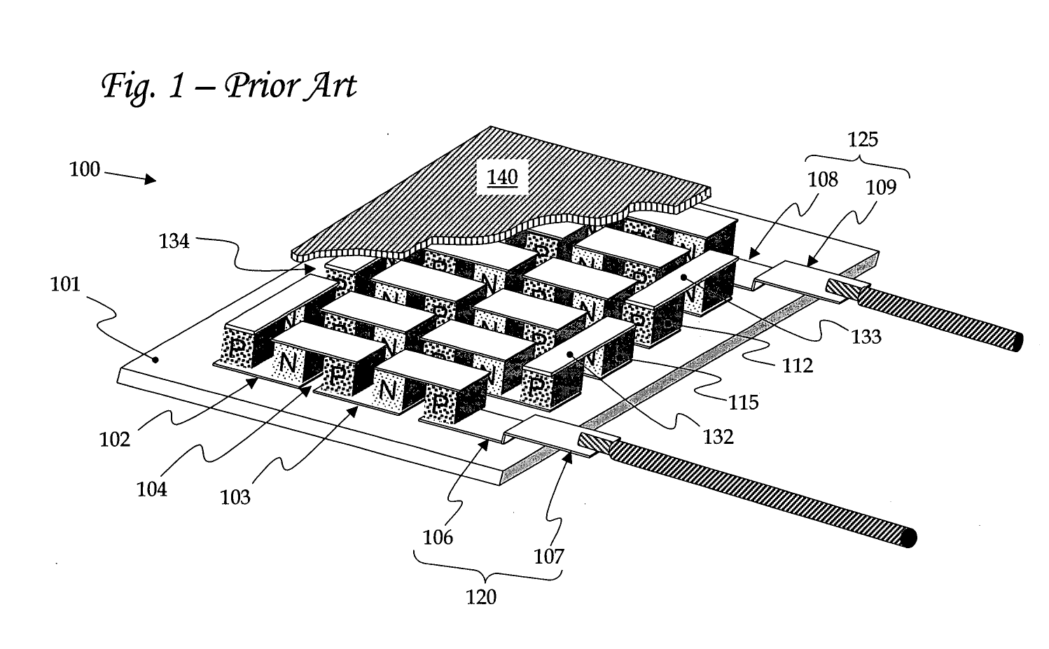

FIG. 1 depicts a module level thermoelectric cooler (TEC) device 100 according to the prior art. As shown in FIG. 1, a plurality of electrically conductive serial contacts 102, 103 are typically provided on an electrically non-conductive ‘bottom’ substrate 101 so that they are initially electrically isolated from each other. Typically, at least one of the serial contacts 106 will have a terminal portion 107 for providing external electrical connection, whereby it serves as a positive electrical terminal 120, while at least one other of the serial contacts 108 will have a terminal portion 109 for providing external electrical connection whereby it serves as a negative electrical terminal 125 for the TEC 100.

A plurality of n-type semiconductor elements 115 and p-type semiconductor elements 112 are typically arranged in an array wherein at least one n-type element 115 and one p-type element 112 are placed upon adjacent serial contacts 102, 103 separated by a gap 104 between the serial contacts 102, 103. In this way, disparate elements, one an n-type element 115 and one a p-type element 112 will be disposed proximate the same gap 104 between adjacent elements 102, 103. In an array including a plurality of n-type elements 115 and p-type elements 112, each serial contact 102, 103 will have disposed upon its opposite ends at least one n-type element 115 at one end, and at least one p-type element 112 at the other end. For illustrative purposes, the surface of each n-type 115 and p-type 112 element in contact with the serial contacts 102, 103 disposed upon the substrate 101 will be termed the ‘bottom’. Likewise, for illustrative purposes, the serial contacts 102, 103 disposed upon the substrate 101 will be termed ‘bottom serial contacts’ 102, 103.

Throughout this description, the term ‘element’, as in ‘a p-type element’, or ‘a first element’, describes a structural unit of a thin film device. In this sense, the term ‘element’ is not used herein to specify a chemical element as would be found on the periodic table of elements. While in embodiments, an element according to the invention may comprise specified elements from the periodic table, for example bismuth, such chemical elements will be referred to herein by their chemical names for clarity.

Therefore, a plurality of serial contacts 132, 133 are disposed atop the n-type 115 and p-type 112 elements in an array of TEC elements. For illustrative purposes, these serial contacts are herein termed ‘top serial contacts’ 132, 133. It should be understood that the designations of orientation (‘bottom’ and ‘top’) are relative, and included in this description only to differentiate the two types of serial contacts in a module level TEC. Each top serial contact 132, 133 is surrounded by gaps 134 so that each top serial contact 132, 133 is isolated from direct contact with every other top serial contact. However, each top serial contact 133, 133 is in contact with at least one n-type element 115 disposed upon one bottom serial contact 102, and in contact with at least one p-type element 112 disposed upon another bottom serial contact 103. Disposed upon the top serial contacts will typically be an electrically non-conductive ‘top substrate’ 140, which may comprise a layer of ceramic or some other suitable material.

Therefore, an arrangement is formed within a TEC device 100 whereby an electrical current may enter the TEC device via an electrical terminal 125, and flow in series through an alternating arrangement of, for example, bottom serial contact 102—n-type TEC element 115—top serial contact 132—p-type TEC element 112—bottom serial contact 103, then flow out of the TEC device through another, opposite electrical terminal 120. As mentioned, a module level TEC 100 according to the prior art is a relatively large, rigid device, and is not well suited for providing efficient cooling to hot spots on a die, nor in applications requiring a relatively small or light cooling solution.

Thermoelectric coolers operate on what is known as a Peltier effect, whereby passing a current through dissimilar conductors results in a temperature increase or decrease at the junction between the conductors, depending on the direction of current flow. When conductors such as the n-type elements and p-type elements described in embodiments of the invention are electrically coupled in series, and an electrical current is applied so that it passes from the n-type element to the p-type element, the temperature at the junction will decrease. Conversely, current passing from a p-type element to an n-type element will cause the temperature to increase at the junction. Therefore, in an array of n-type and p-type elements electrically connected in series, there will be formed a ‘hot’ side of the array and a ‘cold’ side of the array when an electrical current is passed through the array. The TEC elements are connected in serial electrically, but function in parallel thermally. If the direction of current flow though a given junction is reversed, so that the current flows not from the n-type element to the p-type element, but rather the reverse, the temperature at that junction will increase rather than decreasing. Therefore, when the direction of current flow through the array is reversed, the ‘hot’ and ‘cold’ sides of the array will be also reversed.

Because a TEC acts as a ‘heat pump’, moving heat from the cold side of an array to the hot side of an array, a TEC works very well to carry heat away from a heat generating device. The cold side of a TEC may be placed adjacent to a heat generating device, and when activated, the TEC may carry away heat from the heat generating device to a passive or active cooling device placed adjacent to the hot side of the TEC array for removal from the immediate device or system. The more TEC element pairs (an element pair including one n-type and one p-type TEC element) that are provided in a TEC device, the greater will be the overall heat carrying capacity of the TEC device. Heat carrying capacity may also be affected by the current itself.

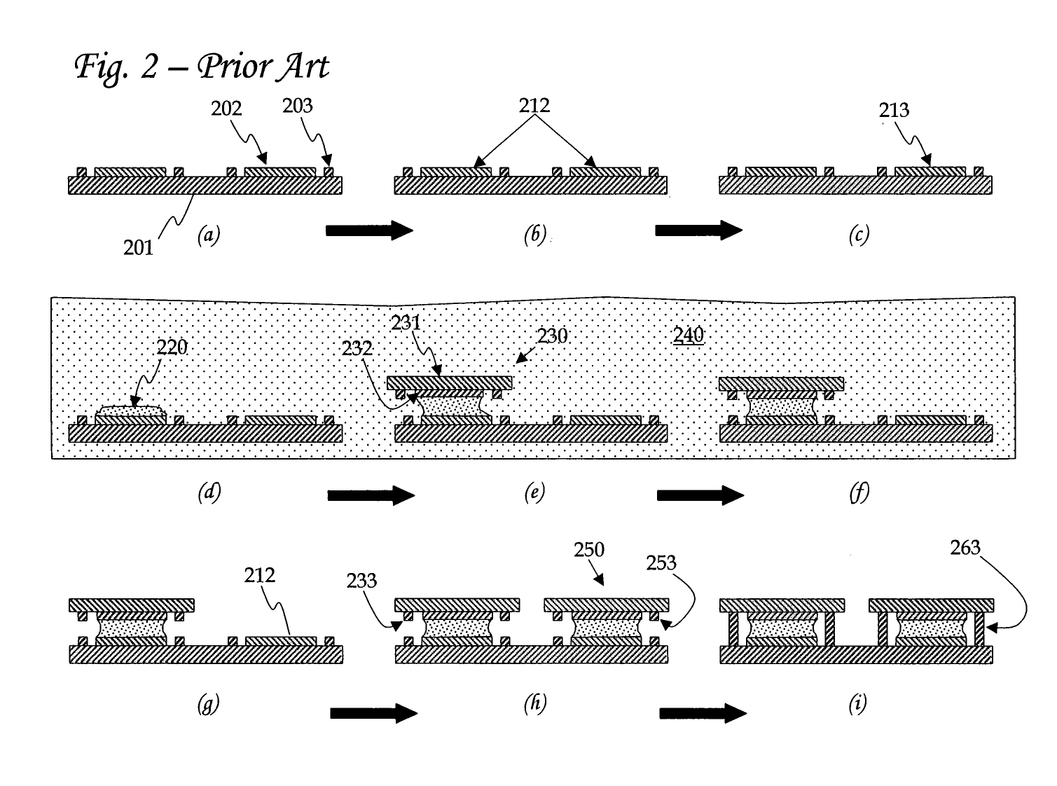

As shown in FIG. 2, a prior art self-assembly method involves disposing hydrophilic gold patterns ‘binding sites’ 202 upon a surface of a substrate 201. Electroplated bases 203 are formed near the periphery of the gold patterns 202. Next, the substrate 201 and gold patterns 202 are soaked in ethanolic alkanethiol solution causing the gold patterns 202 to absorb a hydrophobic alkanethiol self-assembled monolayer (SAM), thus changing the hydrophilic gold patterns 202 into hydrophobic gold patterns 212. In the prior art, these hydrophobic gold patterns 212 are also identified as ‘binding sites’.

Next, in order to selectively self-assemble parts onto only some of the hydrophobic gold patterns 212, the alkanethiol SAM is electrochemically desorbed from the non-selected gold patterns, turning them once again into hydrophilic gold patterns 213. Thereafter, self-assembly will occur only at the hydrophobic gold patterns 212. A hydrocarbon-based lubricant 220 is disposed across the surface of the substrate 201, and the substrate is immersed into a reservoir of water 240. In the water 240, the lubricant 220 remains only on each of the SAM-coated hydrophobic gold patterns 212. Parts 230, each having a main substrate portion 231 and a ‘binding site’ pattern 232, the latter corresponding to the ‘binding site’ hydrophobic gold patterns 212 on the substrate 201, are placed into the water bath 240 with the substrate 201. Due to a capillary driving action between the hydrocarbon-based lubricant 220 and the binding sites 232 on the parts 230, parts 230 are self-aligned and self-assembled onto the hydrophobic gold patterns 212 on the substrate 201. The lubricant 220 may then be polymerized by heat, firmly bonding the parts 230 to the hydrophobic gold patterns 212 on the substrate 201.

Those hydrophilic gold patterns 213 from which the SAM was desorbed remain vacant throughout the self-assembly process just described. However, the SAM absorption and self-assembly steps may be repeated for the remaining vacant hydrophilic gold patterns 213 using entirely different parts 250, allowing, in sequential processes, a plurality of disparate parts to be self-assembled to a substrate 201. Following self-assembly of all parts 230, 250, metal alloy may be electroplated onto corresponding plating bases 203, 233, 253 formed on the substrate 201 and on the parts 230, 250 until a bridge 263 of electroplated metal alloy joins the substrate plating bases 203 with those on the parts 233, 253, forming electrical connections between the parts 230, 250 and the substrate 201.

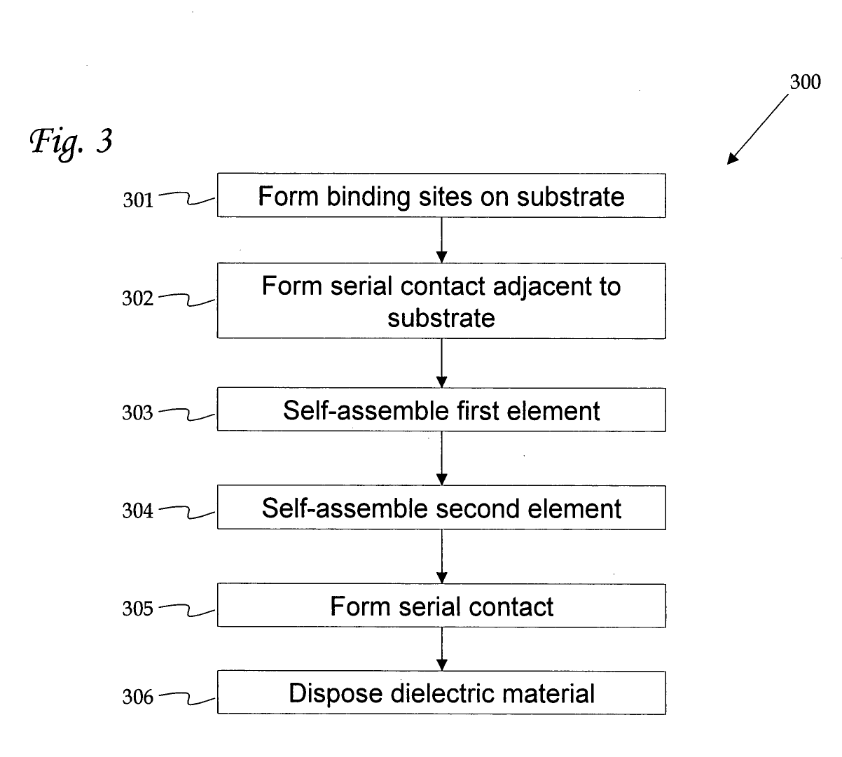

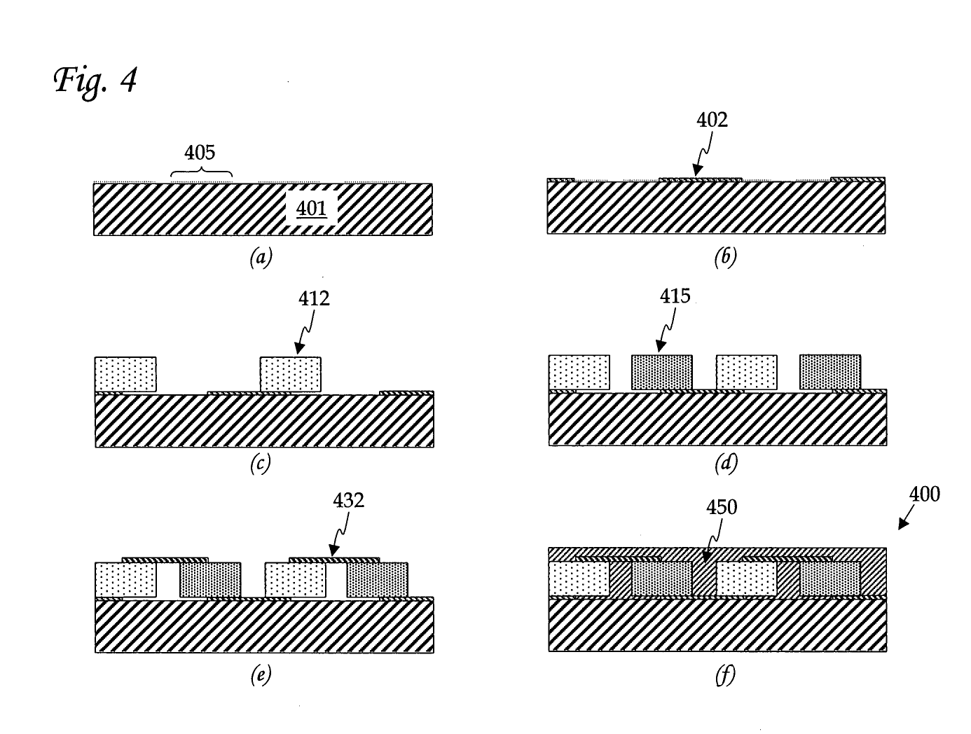

FIG. 3 and FIG. 4 depict an exemplary embodiment of a method 300 of self-assembling a thin film thermoelectric cooling device. Initially, a plurality of binding sites 405 and at least one serial contact 402 are formed, at 301 and 302, adjacent to a substrate 401. Then, at least one first TEC element 412 and at least one second TEC element 415 are self-assembled, at 303, 304, to the binding sites 405. Next, ‘top’ serial contacts 432 are formed, at 305, electrically coupled to the first TEC elements 412 and second TEC elements 415. Finally, a dielectric material 450 may be disposed, at 306, upon and substantially covering the TEC elements 412, 415, binding sites 405, serial contacts 402, 432, and substrate 401. Embodiments of the invented method will now be described in greater detail.

In an exemplary embodiment, a plurality of binding sites 405 are formed, at 301, adjacent to a substrate 401. A substrate 401, in embodiments of the invention, may be a passive cooling device, such as an integrated heat spreader (IHS) or a heat sink, or it may be an active cooling device, such as a refrigeration device, a muitiphase cooling device (liquid-vapor, including heat pipes), a module level TEC, a liquid cooling device, a fan, or others as are known in the art. For simplicity, all active and passive cooling devices may be referred to herein as ‘cooling devices’.

In other embodiments, a substrate 401 may include a heat generating device. Examples of heat generating devices may include integrated circuit devices and other signal processing devices, including but not limited to microprocessors, chipsets, multimedia generating and processing devices (e.g. graphics, audio), input/output (I/O) devices, memory devices, printed circuit boards (PCBs), integrated circuit packages, power regulating devices, optoelectronic devices, and others. Embodiments of an integrated circuit device as a substrate 401 may include partially or completely exposed semiconductor die, or may include packaged semiconductors. However, it should be understood that in embodiments of the invention, a heat generating device may be any device with a positive thermal output, either occasionally or continuously.

In still other embodiments, it may be useful to attenuate or maintain the temperature of an otherwise thermally neutral material or device (collectively herein, ‘thermally neutral device’) that does not generate heat, and may or may not be designed or implemented to aid the cooling of a heat generating device, but rather is thermally affected (heated or cooled) by the environment, by artificial or natural heat sources, or by artificial or natural sources of heat absorption. Alternatively, a substrate 401 may neither be a heat generating device or a cooling device, nor something for which thermal regulation may be useful, but rather, in an embodiment of the invention, a substrate 401 may be a thermally neutral device intended as a ‘carrier’ that may be applied to something for which thermal regulation is intended. In an exemplary embodiment, a substrate 401 may be a portion of an adhesive bandage, pad, blanket, splint or similar item that may be applied to a patient to provide heating or cooling for the treatment of conditions that may benefit from thermal regulation, including thermal injuries (e.g. burns) or other thermally related medical conditions (e.g. hypothermia, heatstroke) and may therefore be a medical device. As should be understood, it may be useful to provide a control mechanism in numerous embodiments so that the amount of thermal modulation provided by a self-assembled TFTEC device may be controlled within an appropriate range, or to an appropriate target. A control mechanism may be implemented as a software program, or as a hardware device including, but not limited to, a rheostatic device, a thermal fuse, a thermal relay, a solid state thermal control circuit, or another control mechanism as may be known in the art. A feedback mechanism or circuit may also be implemented, and may include a thermal sensor thermally or electrically coupled to a control mechanism.

In other embodiments, a substrate 401 may be part of, or be positioned by a medical device, for applying heat or cold during surgical treatment of a patient. Thereby, an embodiment of the invention may include a medical device for providing thermal treatment to a patient, particularly where extremely localized heating or cooling may be useful, but not limited to extremely localize applications. For example, an embodiment could be used to induce constriction or expansion in the diameter of a blood vessel by the application of cold or heat, respectively. In the broadest sense, a substrate 401 may be anything possessing a surface upon which a self-assembled TFTEC may be formed according to embodiments of the invention.

As presented in embodiments of the invention, binding sites 405 may include features or locations on a substrate 401 that have an affinity or receptivity for a reciprocal feature or location (binding site) on a TEC element 412, 415 to be self-assembled, at 303, 304, adjacent to the substrate 401. A binding site 405 may also simply be a location where self-assembly is designated to occur. A binding site 405 may include a material that has an affinity or receptivity by its inherent properties alone, or by properties imparted to it by some treatment provided for that purpose. For example, a binding site 405 may be caused to acquire a magnetic field, by which an affinity or receptivity may be formed to ferrous or other magnetic materials. Alternatively, a binding site 405 may be chemically treated causing it to become hydrophobic or hydrophilic, as may be appropriate. A binding site 405 may simply have a shape or surface texture that would allow a reciprocally shaped or textured binding site 405 to be aligned and retained at the binding site. In other embodiments, binding sites 405 may be chemically, mechanically, magnetically, electrostatically or otherwise receptive to reciprocal binding sites for self-assembly, at 303, 304.

The receptivity of binding sites 405 may also be specialized, so that they are receptive to specific reciprocal binding sites on TEC elements 412, 415 or other elements, but are not receptive to other, non-reciprocal binding sites. Thereby, while TEC elements 412, 415 intended for self-assembly to a binding site 405 may be attracted to, aligned to, and even bonded to the binding site 412, 415, other non-reciprocal binding sites on elements not intended for self-assembly to the binding site may not be attracted to, aligned to, or bonded to the binding site, and may even be repelled by the binding site.

A binding site 405 may also be a location where a binding agent, such as the hydrocarbon lubricant 220 discussed regarding the prior art, may be deposited. Therefore, a substance with the ability or preference for forming a bond with a reciprocal binding site may be disposed onto or proximate a binding site 405. In embodiments, such substances may include adhesives. In other embodiments, such substances may affect the interfacial tension of a liquid medium proximate a binding site 405. Conversely, an entire substrate 401 may have an affinity or preference for forming a bond with a reciprocal binding site, but areas of the substrate 401 where self-assembly is not intended may be covered to prevent bonding, or may be temporarily or permanently treated to remove, reduce, or otherwise modify the amount of affinity or preference those non-selected areas have for bonding with a reciprocal binding site.

In another embodiment, a binding site 405 may have no special affinity or preference for bonding with a reciprocal binding site. However, areas of a substrate 401 not intended as binding sites 405 may somehow repell reciprocal binding sites, or simply prevent alignment and bonding of reciprocal binding sites to those areas, so that reciprocal binding sites tend to migrate to binding sites 405 on the substrate 401 where no such repulsion or prevention is found. The repulsive tendencies may be due to natural properties of a substrate, or they may be induced by some treatment, application, or alteration to those areas of the substrate 401 where self-assembly is not intended. The described treatment, application, or alteration may be permanent, or it may be only temporary in the case that later self-assembly in those areas is intended.

A plurality of binding sites 405 may be disposed, in embodiments of the invention, wherein the size, shape, symmetry, dimensions, orientation, spacing, placement density, and other physical traits of binding sites 405 in an array may be either completely uniform, completely disparate, or partially uniform and partially disparate in any single trait or combination of traits.

Forming a binding site 405 adjacent to a substrate 401 may include the binding site 405 being formed entirely on the surface of a substrate 401. In other embodiments, a binding site 405 may be disposed partially on a substrate 401, and partially on a feature or layer that is disposed on the surface of a substrate 401, or may be disposed entirely on a feature or layer that is disposed on the surface of a substrate 401. In embodiments wherein the surface of a substrate 401 may be partially removed to expose a plane of the substrate 401 other than an exterior surface of the substrate, a binding site 405 may be formed adjacent to the substrate by being formed either partially or entirely upon the exposed plane other than the surface of the substrate 401.

One or more serial contacts 402 may be formed, at 302, adjacent to a substrate 401. For clarity and simplicity herein, the serial contacts 402 will be referred to herein as ‘bottom serial contacts’ to differentiate them descriptively from the later formed ‘top serial contacts’. However, the designations of ‘top’ and ‘bottom’ are not to be interpreted as imparting an implied or express orientation in the described TFTEC embodiments. In embodiments, serial contacts 402 may be formed of an electrically conductive material using any of a number of methods, including lamination, electroplating, sputter deposition, evaporative deposition, lithography, or others according to alternative embodiments. The purpose of a serial contact 402 in a TFTEC is to conduct electricity between TEC elements and throughout a TFTEC array, therefore, a conductive material with low resistance to the flow of electrons may provide for a more efficient TFTEC device.

A serial contact 402 may be formed so that it partially overlaps a binding site 405 so that when a TEC element 412, 415 is self-assembled to the binding site 405, a portion of a TEC element 412, 415 also overlaps a portion of the serial contact 402. Alternatively, a portion of a binding site, or an entire binding site 405, may be formed on a portion of a serial contact 402 so that a portion of a TEC element or an entire TEC element 412, 415 may self-assemble directly onto a serial contact 405. Accordingly, a serial contact 405 be made large enough that two or more TEC elements 412, 415 may be entirely self-assembled onto the serial contact 405, or may be made as small as possible while remaining electrically coupled to two adjacent TEC elements 412, 415. Likewise, there may be great variability in the possible shapes in which serial contacts 405 may be formed, and both the size and shape of serial contacts may be designed to facilitate formation of a highly dense TFTEC array.

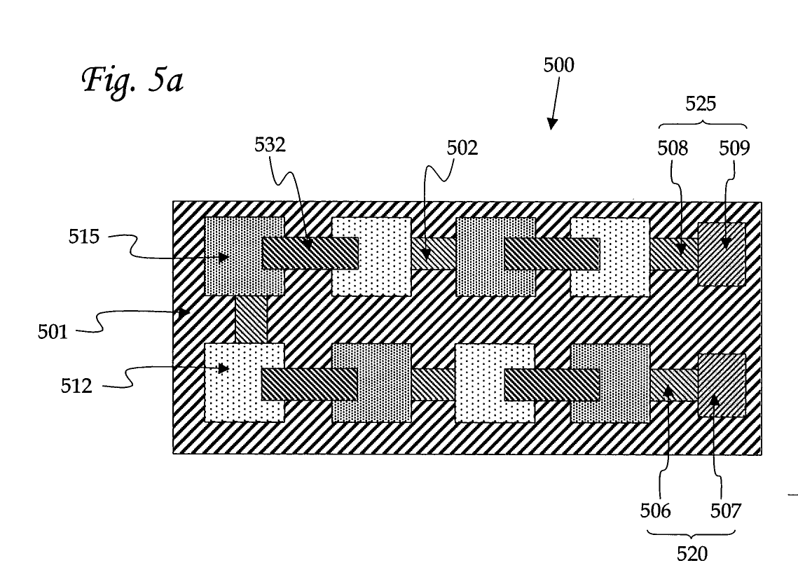

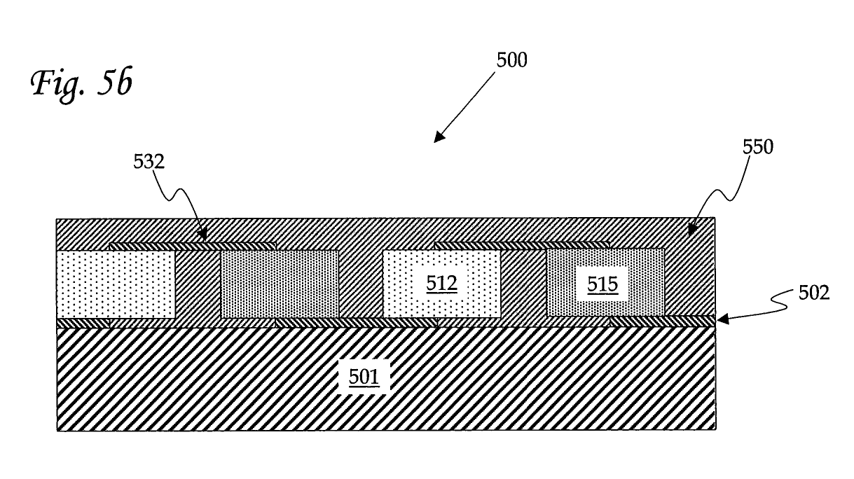

Each serial contact 402 formed on the substrate 401 is generally formed so that it is electrically isolated from any other serial contacts formed on the substrate, and may be electrically isolated from the substrate. However, with reference to FIG. 5, serial contacts 506, 508 that may partially form one of a positive or negative electrical terminal 520, 525 formed on a substrate 401 in a finally formed self-assembled TFTEC device 405 may be electrically coupled to electrically conductive features integrated into the substrate 401 to connect the finally formed self-assembled TFTEC 400 into an electrical circuit.

At least one of a first TEC element 412 may be self-assembled, at 303, to a binding site 405, so as to also be electrically coupled to a serial contact 402. In alternative embodiments, a first TEC element 412 may be an n-type TEC element or it may be a p-type TEC element. In an embodiment wherein an array of TEC elements may be formed according to embodiments of the invention, a plurality of first TEC elements 412 may be self-assembled, at 303, to non-adjacent binding sites so that like-type TEC elements are not aligned with each other across a gap between adjacent bottom serial contacts to be later connected by a later formed top serial contact. Thus, in the finally formed self-assembled TFTEC device 400, the flow of electricity will pass through the device alternating between n-type TEC elements and p-type TEC elements, each connected to the next by either a top serial contact 432 or a bottom serial contact 402. In this manner, electricity will not flow within a self-assembled TFTEC device 400 directly from one n-type TEC element to another n-type TEC element, nor directly from one p-type TEC element to another p-type TEC element.

As described previously, a first TEC element 412 may be self-assembled, at 303, to a binding site 405 that partially overlaps a bottom serial contact 402, or in another embodiment, it may be self-assembled to a binding site 405 located entirely within the boundaries of a bottom serial contact 402. In either case, each first TEC element 412 self-assembled, at 303, to a binding site 405 should be electrically coupled to a bottom serial contact 402 so that electricity may flow from one into the other. Therefore, it should be understood that the nature of a binding site 405 as described earlier may not be such that it completely impedes the flow of electricity from a bottom serial contact 402 into a first TEC element 412, nor from a first TEC element into a bottom serial contact 402 in the case of a reversed flow of electricity.

When the compositions of TEC elements are dissimilar, TEC devices exhibit a temperature decrease at a junction between a serially coupled n-type TEC element and p-type TEC element when a current is passed through them. Self-assembled TEC elements may include, in embodiments, numerous different compositions, some of which will now be discussed. Bismuth telluride may be used as TEC element, as its capacity for pumping heat can be adjusted, and the type charge carrier can be controlled to some extent. In some embodiments, bismuth telluride may also be doped with elements such as antimony (Sb) or selenium (Se). Therefore, in embodiments, TEC elements with dissimilar compositions may be used wherein the element used for doping or the amount of doping may be different between the n-type TEC element and the p-type TEC element. In exemplary embodiments, such doped TEC elements may include (Bi₁₋ₓSbₓ)Te₃ or (BiSb)Te(Se). In other embodiments, the amount of bismuth or tellurium in a TEC element may also be different in an n-type TEC element than in a p-type TEC element. In one such exemplary embodiment, one TEC element may include bismuth telluride (Bi₂Te₃) while another TEC element may include a doped composition, thereby changing the ratio of bismuth to tellurium by changing bonding dynamics in the doped composition. By this description, it should also be clear that the compositions of two self-assembled TEC elements 412, 415, according to embodiments, will inherently be different if one TEC element is doped and the other TEC element is not, even if the amounts of bismuth and tellurium are the same in the two elements. In still other embodiments, a p-type TEC element or an n-type TEC element may include germanium. In an exemplary embodiment, a TEC element may include silicon-germanium (SiGe).

Embodiments of self-assembling a first TEC element 412 may include activating a binding site 405 prior to self-assembly, at 303, of a first TEC element 412 to the binding site. For example, activation may include changing the surface condition of a hydrophilic binding site to make it hydrophobic. Activation may also include magnetizing a binding site, or inducing an electrostatic charge, or applying an adhesive material to which a first element may be aligned and adhered during self-assembly. In other embodiments, activation may encompass other actions which generally enable a binding site to accept (or even attract), align, or retain a first element.

After activating some or all of the binding sites 405 on a substrate 401, in some embodiments, at least some of the activated binding sites may be deselected for self-assembly by deactivating them. This may include returning the surface condition of deselected binding sites to a hydrophilic state in some embodiments, or it may include neutralizing a static charge on the surface of a binding site in another embodiment, or in other embodiments it may include covering the binding site, changing the shape or surface texture, or removing an adhesive substance from the surface of a binding site. Generally, deselecting a binding site by deactivating it will include altering the condition of a binding site that caused it to attain an activated state in the first instance. This may include returning it to its original condition in some embodiments, while in other embodiments, it may include changing the surface condition of a binding site to something other than its original condition, if in its original condition it was in an activated state.

In order for a first element 412 to self-assemble to a binding site 405 on a substrate 401 , the first element should be brought into proximity with the binding site on the substrate so that the binding site on the first element may ‘recognize’ or respond to the activated binding site on the substrate. ‘Recognition’ of the binding site may include, in embodiments, the behavior of a first element being influenced by the activated binding site on the substrate. ‘Responding’ to an activated binding site may include, in an exemplary embodiment, a magnetic binding site on a first element coming within range of a magnetic field from a magnetized binding site on a substrate, so that the first element may be magnetically attracted to and begin to move nearer to the activated binding site on the substrate.

In embodiments, a substrate 401 with activated binding sites may be placed into an environment including at least one first element 412, or a plurality of first elements, while in other embodiments, a plurality of first elements may be placed into an environment containing a substrate 401 with activated binding sites 405. An environment for self-assembly may include a means for providing mobility to the first elements so that they may move into proximity to an activated binding site on a substrate. Such means may be gaseous, liquid, or may even include a flowing solid, such as a powder, granules, or ‘pellets’.

In embodiments, a gaseous environment may include nearly any gaseous element or compound, providing the gaseous element or compound does not damage the TEC elements or substrate, interfere with the self-assembly process, or create an unacceptably hazardous condition. For example, gases which are corrosive to the materials involved, gases which may deactivate or otherwise impair the function of binding sites on a substrate, or gases which may be explosive, pyrophoric, or toxic may not be preferred for use in embodiments of the invention, although they may be used under special conditions and when proper precautions are taken. A gaseous environment may be positively pressurized or negatively ‘depressurized’ relative to the ambient pressure, or it may be equivalent in pressure to the ambient environment, and may likewise be higher than, lower than, or equal to the ambient environment in temperature. In an embodiment, a vacuum environment from which all gases have been evacuated may be used. For simplicity, environments in which there is either a positive or a negative pressure will simply be referred to herein as ‘pressurized’.

In other embodiments, a liquid environment may be used under similar conditions as described for a gaseous environment. In at least one embodiment, water may be used as a liquid environment for self-assembly. Further, the materials in a first element and a substrate should not be soluble in the liquid environment, except where such solubility may be involved in the intended activation of binding sites, deactivation of deselected binding sites, or another intended part of self-assembly such as adhesion of a first element to a binding site on a substrate. If a liquid or gas is effectively inert with regard to the materials and operations involved in self-assembly, providing only a medium in which a first element may be mobile until binding to a binding site, such a liquid or gas may be used.

A flowing solid environment may also be used if it allows a first element to be mobile until binding to a binding site. Such an environment may include, in exemplary embodiments, a powder, granules, or a quantity of small pellets of a solid material. ‘Pellets’, as used in this description, may be small, individual units of a solid possessing nearly any regular or irregular shape or form. In another embodiment, a flowing solid environment may include a large number of first TEC elements providing both a flowing medium for carrying first TEC elements into proximity to binding sites for attachment without the aid of another solid material, and providing the first TEC elements themselves. In describing a ‘solid flowing environment’, powders, granules, pellets, and materials according to other embodiments are referred to as ‘solid’ not because they are rigid, monolithic, or comprise a single unit, but rather to distinguish them from embodiments of a gaseous or liquid medium.

In embodiments, powders, for example, may be agitated by a number of methods and means, and will dislocate and flow in response to such agitation. In response to pressure created by a flowing solid environment, or liquid or gaseous environments as well, first TEC elements will also be dislocated and become mobile within the environment. Agitation of a gaseous, liquid, or solid flowing environment may be caused by rotating, inverting, shaking, stirring, vibrating (e.g. acoustically), inducing a current, or numerous other methods or means. By such agitation, the likelihood that a first TEC element may encounter a binding site on a substrate and bind to that binding site is increased, and the self-assembly process may be accelerated. Also by this method, the chances for achieving a higher yield of binding sites on substrates occupied by bound first TEC elements is improved. Therefore, providing some method for agitating a gaseous, liquid, or flowing solid environment may be beneficial.

Placing into a self-assembly environment a larger number of first TEC elements than are needed for fill all binding sites on a substrate may also help to increase yield as described and accelerate the self-assembly process. Therefore, one should be aware of the total number of binding sites on a substrate that are intended to be filled with first TEC elements, and provide into the self-assembly environment at least enough TEC elements as there are binding sites to be filled, and at the most, as many first TEC elements are as practicable without impairing the ability of the first TEC elements to move about within the self-assembly environment and bind to binding sites without being too frequently dislodged by other still mobile TEC elements.

Self-assembly may be allowed to continue until all binding sites on a substrate intended for self-assembly by first TEC elements are occupied, at which point self-assembly of first TEC elements will be complete. However, if an inadequate number of first TEC elements are present in the self-assembly environment to bind with and occupy all intended binding sites on a substrate, the self-assembly process may be interrupted, and more first TEC elements may be added to the self-assembly environment until enough first TEC elements are present in the environment to bind with and occupy all intended binding sites on the substrate.

After self-assembling first elements to a substrate, the substrate, binding sites, or first TEC elements may be treated to create a strong bond between the first TEC elements and the substrate. In embodiments, heat may be used, or treatment with chemical substances, or an adhesive may be applied, or any number of other treatments that may provide a durable, reliable bond between the first TEC elements and a substrate. In an embodiment, connective structures may be electroplated between features on a first TEC element and features on a substrate, physically and electrically coupling the first TEC elements to the substrate on which they reside.

Once a sufficient number of first TEC elements are self-assembled to binding sites on a substrate, second TEC elements 415 may be self-assembled, at 304, to binding sites 405 on the substrate 401 not selected for self-assembly of first TEC elements 412. Embodiments described above for assembling first TEC elements 412 may also be used to self-assemble second TEC elements 415, however, in embodiments, the types of binding sites or the method for activating a binding site 405 for a second TEC element 415 may be different than for a first TEC element 412. In an exemplary embodiment, a binding site 405 for a first TEC element 412 may be activated by making the binding site 405 hydrophobic, whereas a binding site for a second TEC element 415 may be activated by inducing an electrostatic charge at the binding site.

In embodiments of the invention in which a thin film device requiring more than two types of elements is to be self-assembled, some portion of the binding sites remaining vacant prior to self-assembly of the second TEC elements may be deselected for self-assembly, either by not being activated, or by being activated and subsequently deactivated.

Following self-assembly of the TEC elements 412, 415, serial contacts 432 may be formed, at 305, electrically coupling a TEC element of one type to a TEC element of another type. For simplicity of description, the serial contacts 432 formed after self-assembly of the TEC elements shall be called ‘top’ serial contacts in this description, however, this term should not be interpreted as describing or restricting a particular orientation. The term ‘top’ serial contact is used herein to differentiate the serial contacts described here from the serial contacts formed prior to self-assembly of the TEC elements (‘bottom’ serial contacts).

In an embodiment, an n-type TEC element may be coupled to a p-type TEC element by a top serial contact 432. It should be noted that any given n-type and p-type elements physically and electrically coupled to a top serial contact will generally not be the same n-type and p-type element pair physically and electrically coupled to a single bottom serial contact, however, a top serial contact and a bottom serial contact may both be directly electrically coupled to one of the TEC elements in a pair of disparate type TEC elements. This is better understood when the serial current flow through TEC elements in a TFTEC array is recalled from the earlier discussion in this specification, and that current flows into an element through one of either a top or bottom serial contact, then flows out of the element through the other of either a top or bottom serial contact.

In general, forming top serial contacts 432 according to embodiments of the invention may include any of the methods discussed earlier for forming bottom serial contacts 402. Likewise, a top serial contact 432 in some embodiments may entirely overlap a TEC element 412, 415, or it may only partially overlap a TEC element, however, in generally, a top serial contact will be formed electrically coupled to at least one TEC element. As with bottom serial contacts, in embodiments, a top serial contact may be formed electrically coupled to only one TEC element, and provide a means for electrically coupling to an electrically conductive feature external to the TFTEC so that the top serial contact may act as a positive electrical terminal or a negative electrical terminal for the TFTEC.

Serial contacts carry electrical current flow from one TEC element to another, therefore, in various embodiments serial contacts should be made of an electrically conductive material, such as a metal. Serial contacts, top and bottom, may also be formed of metallic alloys, containing more than one type of metal in various embodiments. In general, serial contacts may be formed of any conductive material which can be electrically coupled to a TEC element.

In embodiments, a dielectric material 450 may then be disposed, at 306, upon the substrate 401, binding sites 405, serial contacts 402, 432, and TEC elements 412, 415. A dielectric material 450 may be disposed by vapor deposition methods, such as chemical vapor deposition (CVD) in an embodiment, or by spin-in methods in another embodiment. Exemplary embodiments of a vapor deposited dielectric material 450 may include an oxide material or a nitride material. Exemplary embodiments of a spin-on dielectric 450 may include polyimide, spin-on glass (SOG), resist, or other such materials. In general, any applicable dielectric material 450 possessing a breakdown voltage higher than that applied to the self-assembled TFTEC in the course of use may be acceptable. When beneficial, depending on the type of dielectric material used, exposure to a radiation or heat source may be used to cure the dielectric material 450. A dielectric material may be disposed, in embodiments, so that it substantially covers at least a first element and a second element. For example, the dielectric may form a contiguous layer adjacent to the TFTEC. In another embodiment, a dielectric material may flow among the structure of a TFTEC so that it occupies all or nearly all the spaces in the structure of a TFTEC. A dielectric may also substantially cover at least a first element and a second element by forming a thin barrier layer on a single exposed surface of a first element and a second element. These exemplary embodiments do not include all the possible embodiments of a dielectric material substantially covering at least a first and second element of a self-assembled TFTEC, and many others may be provided without departing from the spirit of the invention.

Thus, as described throughout the prior discussion and shown in FIGS. 5a and 5b, a self-assembled TFTEC 500 includes a substrate 501 upon which are formed a plurality of electrically conductive serial contacts (‘bottom serial contacts’) 502. The serial contacts 502 may have binding sites formed upon them, or they may overlap a binding site on a substrate 501. Binding sites, depending upon how they are formed, may not be visible structures. For example, a binding site formed by chemically treating an area of a substrate 501 to change its affinity for water may not be visible to the naked eye. Binding sites are not individually depicted in the figures, however, they are described to be located on the portion of a substrate 501 or a serial contact 502 to which a TEC element 512, 515 is physically coupled.

A TFTEC as in embodiments of the invention may have alternating first 512 and second 515 TEC elements, which may be n-type TEC elements and p-type TEC elements. The TEC elements 512, 515 may be self-assembled to a substrate 501 partially or fully overlapping a bottom serial contact 502. After self-assembly of all TECs 512, 515, at least one serial contact 532 (‘top serial contact’) may be formed physically and electrically coupled with at a first TEC element 512 and a second TEC element 515. As shown, the top 532 and bottom 502 serial contacts connected alternating first 512 and second 515 TEC elements in a serial relationship, such that when an electrical current is introduced to a terminal 520, 525 of the self-assembled TFTEC 500, the current will flow serially through the self-assembled TFTEC 500.

At least one serial contact 506 in a self-assembled TFTEC will be provided with a means, usually a feature 507, to which an external electrical source may be electrically coupled. In this way, the serial contact 506 and the feature 507 may function as at least one of a positive or negative electrical terminal 520. Additionally, at least one other serial contact 508 in the self-assembled TFTEC may be likewise provided with a means 509 to which an external electrical source may be electrically coupled, thus the serial contact 508 and means 509 may function as the other of a positive or negative electrical terminal. Thereby, a self-assembled TFTEC 500 may be included in an electrical circuit.

A dielectric material 550 is disposed substantially covering the serial contacts 502, 532, TFTEC elements 512, 515, and binding sites. Positive or negative electrical terminals 520, 525 may be partially covered by dielectric material 550, or left completely uncovered, however, they will generally not be completely covered as an exposed portion of the electrical terminals 520, 525 for electrically coupling them to a circuit should generally be provided.

One of the benefits of a self-assembled TFTEC as described in embodiments of the invention is that efficient and effective thermal management can be implemented even to small areas of a device where conventional module level TEC devices may not be implemented, or may not provide the same effectiveness or efficiency of thermal management. In an exemplary embodiment, a heat generating device such as a semiconductor device may have a relatively small hot spot adjacent to only a small portion of its total external surface area. As described here, a ‘hot spot’ is a portion of a device exhibiting a higher temperature than other areas of the device. This may be due to higher thermal output from that portion of the device, or it may be because that portion of the device is thermally coupled to a portion of a heat generating device with a higher thermal output than other portions of the heat generating device. In these or other possible situations, one may want to provide greater thermal management capabilities adjacent to a hot spot on a device than adjacent to other portions of a device.

According to embodiments of the invention, a self-assembled TFTEC 600 may be formed adjacent to a device 601 so that a greater number of TFTEC elements 602 are arranged adjacent to a hot spot of a device 610 than are arranged adjacent to other portions of the device 620. Therefore, the TFTEC elements 602 arrayed adjacent to the hot spot 610 may be provided in a more dense arrangement, providing greater thermal management capability than adjacent to other portions of the device 601. The density of arrangement of TEC elements upon a substrate may be referred to as ‘packing density’, and variations in the packing density across a substrate may be referred to as ‘differential packing density’. As certain portions of a device may have hot spots, and these hot spots may be known by empirical means, by modeling device operation, or perhaps even by the judgment of one skilled in the art, it may be possible to design and form a self-assembled TFTEC so that sufficient thermal management capability is provided for each of the several portions of a device, while not providing excessive thermal management capability where it is not needed. In this way, embodiments of the invention may be formed with minimum waste of materials and space in situations where such waste would increase the size or decrease the cost competitiveness of a device including an embodiment of the invention.

Packing density may be increased by embodiments wherein the size or shape of the TEC elements may differ. As should be readily appreciated, the shape of the TEC elements may allow for an increase in density by reducing the amount of unused space between adjacent elements. In an exemplary embodiment, substantially square TEC elements maybe arranged more densely than circular TEC elements. Likewise, other shapes of TEC elements may also provide for increased packing density, particularly when the shape of a side of a TEC element is closely reciprocal to the side of an adjacent TEC element, eliminating the unused space that may be found between adjacent TEC elements having non-reciprocal sides. Not all TEC elements according to an embodiment need have the same shape. However, due to the somewhat random attachment scheme of TEC elements in a self-assembly environment, it may be beneficial for all n-type TEC elements to be similarly shaped, and all p-type TEC elements to be similarly shaped, even if the n-type TEC elements are shaped differently from the p-type TEC elements. In the same way, the size of TEC elements may be selected so that maximum packing density may be achieved, although it may be beneficial for all n-type TEC elements to be of a similar size, and all p-type TEC elements to be of a similar size, even if the n-type TEC elements are sized differently from the p-type TEC elements. Of course, the shapes or sizes of TEC elements may also differ as described although not disposed directly adjacent to a hot spot.

Additionally, a self-assembled TFTEC according to embodiments of the invention may be formed in intimate contact with a device, reducing or eliminating interceding materials that may hinder thermal conduction away from a heat generating device, and reducing the efficiency of a thermal management solution. In an exemplary embodiment, a self-assembled TFTEC may be provided directly upon the surface of a semiconductor die. In other embodiments, a self-assembled TFTEC 705 may be provided on, or included within a heat generating device 701 such as a semiconductor die package. In still other embodiments, a self-assembled TFTEC 705 may be formed directly upon the surface of an integrated heat spreader (IHS) 703 so that when the IHS is assembled to a heat generating device 701 such as a integrated circuit die or die package, the TFTEC 705 may be interposed directly between the IHS 703 and the heat generating device 701. As should be understood from this description, embodiments may include a self-assembled TFTEC 705 provided between a heat generating device 701, such as an integrated circuit device, and an IHS 703, whether the TFTEC 705 is self-assembled onto the IHS 703 or onto the heat generating device 701.

In another such embodiment, when the IHS is assembled to a die or die package, the TFTEC 707 may be located on an opposite surface of the IHS 703 from that surface that is in contact with a heat generating device 701. In embodiments wherein a surface of a passive or active cooling device 702 may be provided thermally coupled to an IHS 703, a self-assembled TFTEC 707 may be formed upon that surface or another surface of the passive or active cooling device. As may be apparent by this description, it is also possible in embodiments for a plurality of self-assembled TFTECs 705, 707 to be provided to move heat more efficiently and effectively away from a heat generating device 701 and to or through a cooling device or a plurality of cooling devices 703, 702. Thus, an embodiment of the invention may include an assembly of at least one heat generating device 701 and at least one self-assembled TFTEC 705. Another embodiment may include at least one self-assembled TFTEC 707 and at least one cooling device 702, 703. Still another embodiment may include an assembly 700 including at least one heat generating device 701, at least one cooling device 702, 707 and at least one self-assembled TFTEC 705.

Although a self-assembled TFTEC may be formed in intimate contact with a heat generating device or a cooling device, in embodiments, a thermal interface material (TIM) may be disposed between a self-assembled TFTEC and a heat generating device or a cooling device. In an exemplary embodiment, a self-assembled TFTEC may be formed on a heat generating device, and a TIM may be disposed between the TFTEC and a cooling device positioned adjacent to the TFTEC. Thereby, thermal energy may be efficiently moved from the heat generating device through the TFTEC and TIM to the cooling device. A TIM that may be used according to embodiments of the invention may include thermal grease, a thermal gasket, a solder TIM, a cold formed TIM, or other materials or combinations thereof as may be appropriate.

According to embodiments of the invention, a self-assembled TFTEC may be formed directly upon a semiconductor die before the die is separated from a wafer. In such embodiments, the formation of the self-assembled TFTEC may be considered a part of the wafer fabrication process. Accordingly, a semiconductor die with a self-assembled TFTEC formed upon it may be packaged so that the TFTEC is located within the semiconductor package.

The foregoing detailed description and accompanying drawings are only illustrative and not restrictive. They have been provided primarily for a clear and comprehensive understanding of the embodiments of the invention, and no unnecessary limitations are to be understood therefrom. Numerous additions, deletions, and modifications to the embodiments described herein, as well as alternative arrangements, may be devised by those skilled in the art without departing from the spirit of the embodiments and the scope of the appended claims.

I claim:

1. A method for forming thin film devices, comprising:
disposing a plurality of binding sites adjacent to a substrate;
disposing first and second electrically conductive serial contacts at least partially adjacent to the substrate;
selectively self-assembling at least one of a first element to a binding site, the first element electrically coupled to a first surface of the first serial contact;
selectively self-assembling at least one of a second element to another binding site, the second element electrically coupled to a first surface of the second serial contact; and
disposing at least one other electrically conductive serial contact electrically coupled to a second surface of at least the first element and the second element.

2. The method of claim 1, wherein the binding sites comprise patterned features.

3. The method of claim 1, wherein the substrate comprises at least one of an integrated circuit device, a signal processing device, an active cooling device, and a passive cooling device.

4. The method of claim 1, wherein selectively self-assembling the first element comprises activating a plurality of binding sites, and then deactivating a subset of the activated binding sites.

5. The method of claim 1, wherein selectively self-assembling the second element comprises activating the other binding site.

6. The method of claim 1, wherein selectively self-assembling further comprises exposing activated binding sites to at least one of the first and second elements in at least one of a liquid environment, a gaseous environment, a vacuum environment, and a flowing solid medium environment.

7. The method of claim 1, wherein selectively self-assembling further comprises agitating the environment to cause at least one of the elements to occupy a binding site.

8. The method of claim 1, wherein the thin film device is a thin film thermoelectric device.

9. The method of claim 1, wherein the first element comprises at least one of a p-type TEC element and an n-type TEC element, and the second element comprises the other of a p-type TEC element and an n-type TEC element.

10. The method of claim 1, wherein at least one of the first element and the second element comprise at least one of bismuth, tellurium, antimony, germanium and selenium.

11. The method of claim 1, wherein disposing at least one other electrically conductive serial contact comprises forming an electrically conductive pattern electrically coupled with at least the first element and the second element.

12. The method of claim 1, wherein selectively self-assembling comprises disposing first elements and second elements more densely arranged corresponding to at least one hot spot on a heat generating device or a cooling device than to other portions of the heat generating device or the cooling device.

13. The method of claim 1, further comprising disposing a dielectric material so that it substantially covers at least the first element and the second element.

14. A thin film thermoelectric apparatus comprising:
a substrate;
at least one self-assembled p-type TEC element and at least one self-assembled n-type TEC element disposed adjacent to the substrate; and
metallization electrically coupled to the ‘p’ element and ‘n’ element.

15. The apparatus of claim 14, wherein at least one of the p-type TEC elements and n-type TEC elements comprise at least one of bismuth, tellurium, antimony, germanium and selenium.

16. The apparatus of claim 14, wherein the substrate comprises at least one of an integrated circuit device, a signal processing device, an active cooling device, and a passive cooling device.

17. The apparatus of claim 14, wherein the metallization comprises at least one electrically conductive serial contact.

18. The apparatus of claim 14, further comprising a dielectric material substantially covering the at least one p-type TEC element and the n-type TEC element.

19. The apparatus of claim 14, further comprising a plurality of p-type TEC elements and n-type TEC elements arranged more densely corresponding to at least one hot spot on the substrate than corresponding to other portions of the substrate.

20. The apparatus of claim 14, wherein the self-assembled n-type TEC elements may differ from the self-assembled p-type elements in at least one of shape and size.

21. An assembly, comprising:
at least one heat generating device;
at least one cooling device; and
at least one self-assembled thin film thermoelectric cooling (TFTEC) device including a plurality of TEC elements, the TFTEC disposed between the at least one heat generating device and the at least one cooling device.

22. The assembly of claim 21, wherein the heat generating device is at least one of a microprocessor, a chipset, a multimedia processing device, an input/output device, a memory device, a printed circuit board, an integrated circuit package, a power regulating device, and an optoelectronic device.

23. The assembly of claim 21, wherein the cooling device including at least one of an integrated heat spreader, a passive heat sink, a refrigeration device, a multiphase cooling device, a module level TEC, a fan, and a liquid cooling device.

24. The assembly of claim 21, wherein the plurality of TEC elements comprise an array more densely arranged corresponding to a hot spot of the heat generating device than corresponding to other portions of the heat generating device.

25. The assembly of claim 21, wherein the self-assembled TFTEC is disposed directly upon a semiconductor die.

26. The assembly of claim 21, wherein a thermal interface material (TIM) may be disposed adjacent to the self-assembled TFTEC.

27. The assembly of claim 21, wherein the thermal affect of the self-assembled thin film thermoelectric cooling device may be controlled by at least one of changing the amount of an electrical current provided to the TFTEC and changing the direction of an electrical current provided to the TFTEC.

28. The assembly of claim 21, further comprising a control mechanism capable of controlling the thermal properties of the self-assembled TFTEC.

29. An assembly, comprising:
a thermally neutral device; and
at least one self-assembled thin film thermoelectric cooling (TFTEC) device thermally coupled to the thermally neutral device.

30. The assembly of claim 29, wherein the self-assembled thin film thermoelectric cooling device changes the thermal properties of the thermally neutral device relative to the ambient environment.

31. The assembly of claim 29, wherein the assembly is a medical device for providing thermal treatment to a patient including at least one of heating and cooling.

32. The assembly of claim 29, wherein the thermal affect of the self-assembled thin film thermoelectric cooling device may be controlled by at least one of changing the amount of an electrical current provided to the TFTEC, changing the direction of an electrical current provided to the TFTEC and changing the proximity of the TFTEC to the thermally neutral device.

33. The assembly of claim 29, further comprising a control mechanism capable of controlling the thermal properties of the self-assembled TFTEC.
